(19) United States
(12) Patent Application Publication
(10) Pub. No.: US 2026/0192413 A1
(43) Pub. Date: Jul. 9, 2026

(54) MACHINE TOOL

(71) Applicant: FANUC CORPORATION, Minamitsuru-gun, Yamanashi (JP)

(72) Inventor: Taisei FUJIMOTO, Minamitsuru-gun, Yamanashi (JP)

(21) Appl. No.: 18/865,483

(22) PCT Filed: Sep. 27, 2022
(86) PCT No.: PCT/JP2022/035865

§ 371 Date: Nov. 13, 2024

(51) Int. Cl. B23Q 17/09; G01R 21/00

(52) U.S. Cl. CPC B23Q 17/0952; G01R 21/00

(57) ABSTRACT

A machine tool according to one embodiment of the present disclosure that is capable of highly precisely ascertaining power consumption comprises: a plurality of power verification targets; a power meter singly provided in an electrical pass that supplies power to all of the power verification targets; and a control device that controls the plurality of power verification targets. The control device includes a measurement control unit that operates the power verification targets one at a time and acquires detected values from the power meter during operation of the power verification targets, thereby measuring a reference power consumption of each of the power verification targets.

### TECHNICAL FIELD

The present invention relates to a machine tool.

### BACKGROUND ART

For the systems that supply power from a distribution board to a plurality of electrical devices, a technique has been proposed to receive current waveform and voltage waveform measured at the distribution board, and estimate the power consumption of an electrical device (power verification target) from the current waveform of the electrical device (see, for example, Patent Document 1). Patent Document 1 has further proposed correcting the power, based on the power consumption pattern of each electrical device.

### CITATION LIST

### Patent Document

Patent Document 1: Japanese Unexamined Patent Application, Publication No. 2015-102526

### DISCLOSURE OF THE INVENTION

### Problems to be Solved by the Invention

In a machine tool with a plurality of power verification targets including a plurality of drive axes and simple operation mechanisms, the power consumption of each power verification target may be desired to be estimated. However, using the methods such as those disclosed in Patent Document 1 may lead to inaccurate measurement of power consumption due to degradation or other factors affecting the power verification targets.

### Means for Solving the Problems

A machine tool according to one aspect of the present disclosure includes: a plurality of power verification targets; a power meter singly provided on an electrical pass that supplies power to all of the power verification targets; and a control device that controls the plurality of power verification targets. The control device includes a measurement control unit that operates the power verification targets one at a time, and measures the reference power consumption of each power verification target by acquiring the detection value of the power meter during the operation of each power verification target.

### Effects of the Invention

According to the present disclosure, power consumption can be accurately measured.

### BRIEF DESCRIPTION OF THE DRAWINGS

FIG. 1 is a block diagram illustrating the configuration of a machine tool according to one embodiment of the present disclosure.

### PREFERRED MODE FOR CARRYING OUT THE INVENTION

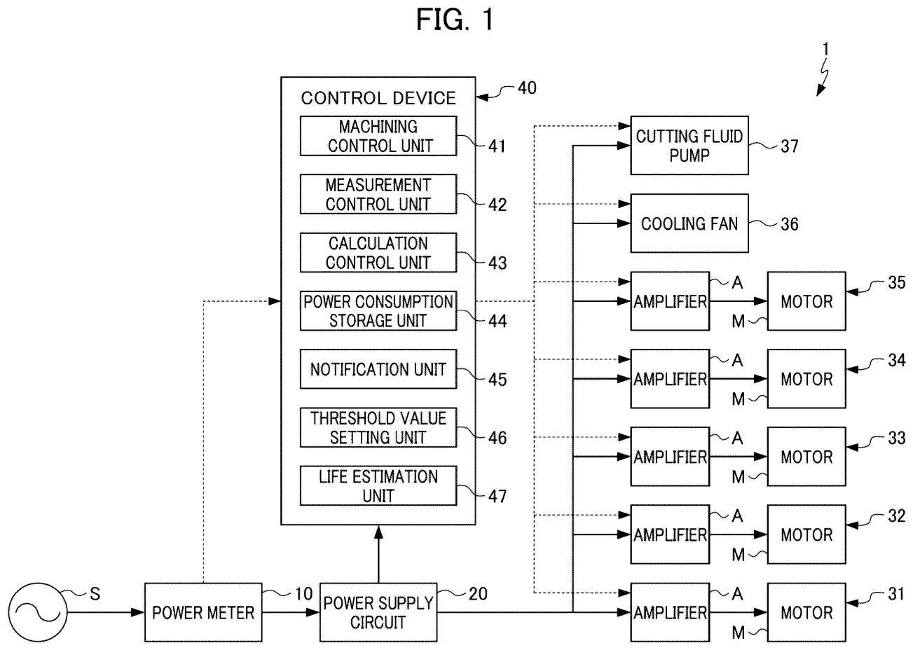

Hereinafter, embodiments of the present disclosure will be described with reference to the drawings. FIG. 1 is a block diagram illustrating the configuration of a machine tool 1 according to one embodiment of the present disclosure. In FIG. 1, the solid arrows indicate electrical pass for supplying power, and the dashed arrows indicate paths for transmitting information (wireless transmission is also allowed).

The machine tool 1 includes one power meter 10, a power supply circuit 20, a plurality of power verification targets 31 to 37, and a control device 40. The machine tool 1 executes machining by driving the power verification targets 31 to 37 using power supplied from an AC power source S.

The power meter 10 is provided in an electrical pass that supplies power to all of the power verification targets 31 to 37. In the present embodiment, the power meter 10 is provided in the electrical pass that supplies power from the AC power source S to the power supply circuit 20 that distributes power to all of the power verification targets 31 to 37. In order to accurately measure the power consumption of the power verification targets 31 to 37, the power meter 10 is preferably provided in an electrical pass that does not supply power to devices that are not controlled by the control device 40. The power meter 10 may detect power or a value that can be used to calculate power. For example, the power meter 10 may be configured to detect a current value that can be used to calculate power through multiplication by the voltage value of the AC power source S.

The power supply circuit 20 converts the AC power supplied from the AC power source S into DC power with voltages required by the power verification targets 31 to 37 and the control device 40. The power supply circuit 20 may output a plurality of different voltages in accordance with the specifications of the power verification targets 31 to 37 and the control device 40.

The power verification targets 31 to 37 are components controlled by the control device 40 and consume power. The power verification targets 31 to 37 include servo mechanisms 31 to 35 that are feedback-controlled, and simple operation mechanisms (cooling fan 36 and cutting fluid pump 37) that are not feedback-controlled. The servo mechanisms 31 to 35 each include a motor M and an amplifier A that drives the motor M. The servo mechanisms 31 to 35 are drive mechanisms for the drive axes (including a main spindle) that relatively move a tool and a workpiece.

The control device 40 controls the operation of the power verification targets 31 to 37. Specifically, the control device 40 includes a machining control unit 41, a measurement control unit 42, a calculation control unit 43, a power consumption storage unit 44, a notification unit 45, a threshold value setting unit 46, and a life estimation unit 47. The control device 40 may be implemented by one or more computer devices including memory, processors, input/output interfaces, and the like, executing an appropriate control program. In the present embodiment, the control device 40 is a so-called numerical control (NC) device. The components of the control device 40 classify the functions of the control device 40, and may not necessary be clearly distinguished in terms of physical configuration or program configuration.

The machining control unit 41 controls the operation of the power verification targets 31 to 37 in accordance with a machining program described in, for example, G-code. The machining control unit 41 may be configured similarly to known numerical control devices.

The measurement control unit 42 operates the power verification targets 31 to 37 one at a time and measures the reference power consumption of each power verification target by acquiring the detection value of the power meter 10 during the operation of the power verification targets 31 to 37. The measurement control unit 42 preferably measures the reference power consumption of at least all of the servo mechanisms 31 to 35 one at a time in sequence, among the power verification targets 31 to 37. In this case, the measurement control unit 42 preferably operates the servo mechanisms 31 to 35 under constant conditions to minimize measurement errors. Specifically, the measurement control unit 42 may be configured to operate the servo mechanisms 31 to 35 at predetermined torque, such as the rated torque, to measure the reference power consumption.

The measurement control unit 42 is preferably configured to operate the power verification targets 31 to 37 at a predetermined timing, such as at startup of the machine tool 1. In order to minimize the reduction in the operating rate of the machine tool 1 due to the measurement of reference power consumption, the timing of the operation of the power verification targets 31 to 37 for measuring the reference power consumption may be set, for example, to the time of startup or shutdown of the machine tool 1 after a predetermined period has elapsed since the last measurement of the reference power consumption. The specific interval for measuring the reference power consumption may be set, for example, to a period between one week and three months inclusive.

In this manner, by operating the power verification targets 31 to 37 one at a time and measuring the reference power consumption, which is the power consumption by operating the power verification targets 31 to 37 under predetermined input conditions, the measurement control unit 42 can capture the reference power consumption that reflects changes due to degradation of the power verification targets 31 to 37. The control device 40 can estimate the power consumption of the power verification targets 31 to 37, based on the input values for operating the power verification targets 31 to 37; however, by correcting the estimated value of the power consumption during machining in consideration of the changes in the reference power consumption, the power consumption of the power verification targets 31 to 37 can be estimated with high accuracy.

The calculation control unit 43 calculates the current power consumption of the simple operation mechanisms 36 and 37 by subtracting the power consumption of the power verification targets (servo mechanisms) 31 to 35 other than the simple operation mechanisms 36 and 37 from the detection value of the power meter 10 during the operation of the plurality of power verification targets 31 to 37 including the simple operation mechanisms 36 and 37. This allows for highly accurately estimating the actual power consumption of the simple operation mechanisms 36 and 37, which cannot be estimated from input values. The calculation control unit 43 may be configured to calculate the power consumption of the simple operation mechanisms 36 and 37 during the machining operation executed by the machining control unit 41. In order to more accurately calculate the power consumption of the simple operation mechanisms 36 and 37, the calculation control unit 43 may operate the servo mechanisms 31 to 35 under the same conditions as during the measurement of the reference power consumption by the measurement control unit 42. Since the power consumption of the on-off controlled simple operation mechanisms 36 and 37 is considered to be constant, the power consumption calculated by the calculation control unit 43 for the simple operation mechanisms 36 and 37 may be treated as the reference power consumption in a standard operating state.

The power consumption storage unit 44 stores the reference power consumption measured by the measurement control unit 42 and the power consumption calculated by the calculation control unit 43 for each of the power verification targets 31 to 37. This allows the user to easily confirm whether there has been any change in power consumption due to the degradation of the power verification targets 31 to 37.

The notification unit 45 externally provides a notification when the reference power consumption exceeds a power threshold value set for each power verification target. The reference power consumption of the power verification targets 31 to 37 may increase due to failure or aging, even if the load remains constant. In a case where the reference power consumption of the power verification targets 31 to 37 exceeds the power threshold value, the power threshold value serves for determining a high likelihood of failure or end-of-life of the power verification targets 31 to 37. In other words, in a case where the reference power consumption of the power verification targets 31 to 37 increases, the machine tool 1 prompts the user to replace or maintain the power verification targets 31 to 37. The power threshold value may be configured to be input by the user, but is preferably configured to be automatically set or updated by the threshold value setting unit 46.

The threshold value setting unit 46 sets the power threshold value used by the notification unit 45.

Specifically, the threshold value setting unit 46 may be configured, in a case where the power verification targets 31 to 37 are replaced to set the power threshold value for the replaced power verification targets 31 to 37, based on the reference power consumption immediately before the replacement of the power verification targets 31 to 37. By setting the power threshold value to the reference power consumption at the time when the power verification targets 31 to 37 are replaced, that is, when the user determines that the power verification targets 31 to 37 need to be replaced, the replacement can be prompted when the power verification targets 31 to 37 have deteriorated to the same extent as when previously replaced by the user.

The threshold value setting unit 46 may set the power threshold value for each of the power verification targets 31 to 37, based on a plurality of reference power consumption values stored in the power consumption storage unit 44 immediately before a plurality of replacements of the power verification targets 31 to 37, respectively. In other words, for example, by setting the power threshold value to an average value of the reference power consumption values immediately before the plurality of past replacements, a more appropriate power threshold value can be set for each of the power verification targets 31 to 37.

The life estimation unit 47 estimates the life of each of the power verification targets 31 to 37, based on a plurality of reference power consumption values stored in the power consumption storage unit 44 for each of the power verification targets 31 to 37. Specifically, the life estimation unit 47 calculates the time until the reference power consumption of each of the power verification targets 31 to 37 is expected to reach the power threshold value, based on the time variation in the reference power consumption of each of the power verification targets 31 to 37. By presenting the user with the time until the reference power consumption is expected to reach the power threshold value, the replacement parts for the power verification targets 31 to 37 can be prepared at an appropriate timing, thereby minimizing downtime.

As described above, the machine tool 1 according to the present embodiment can determine the replacement timing of the power verification targets 31 to 37 with relatively high accuracy and accurately estimate the actual power consumption of the power verification targets 31 to 37, since the measurement control unit 42 measures the reference power consumption of the power verification targets 31 to 37.

Further, the following appendices are disclosed regarding the above embodiment and variations.

### Appendix 1

The machine tool (1) includes: a plurality of power verification targets (31 to 37) ; a power meter (10) singly provided in an electrical pass that supplies power to all of the power verification targets (31 to 37); and a control device (40) that controls the plurality of power verification targets (31 to 37). The control device (40) includes a measurement control unit (42) that operates the power verification targets (31 to 37) one at a time and measures the reference power consumption of each of the power verification targets (31 to 37) by acquiring the detection value of the power meter (10) during the operation of the power verification targets (31 to 37).

### Appendix 2

The measurement control unit (42) may operate the power verification targets (31 to 37) at a predetermined timing.

### Appendix 3

The control device (40) may further include a notification unit (45) that externally provides a notification when the reference power consumption exceeds a power threshold value set for each of the power verification targets (31 to 37).

### Appendix 4

The control device (40) may further include a threshold value setting unit (46) that, in a case where the power verification targets (31 to 37) are replaced, sets the power threshold value for the replaced power verification targets (31 to 37), based on the reference power consumption immediately before the replacement.

### Appendix 5

The control device (40) may further include a power consumption storage unit (44) that stores the reference power consumption for each of the power verification targets (31 to 37), and a life estimation unit (47) that estimates the life of the power verification targets (31 to 37), based on a plurality of reference power consumption values.

### Appendix 6

The plurality of power verification targets (31 to 37) may include servo mechanisms (31 to 35) including motors (M) and amplifiers (A).

### Appendix 7

The plurality of power verification targets (31 to 37) may include simple operation mechanisms (36, 37) that are not feedback-controlled, in which the control device (40) may further include a calculation control unit (43) that calculates the current power consumption of the simple operation mechanisms (36, 37) by subtracting the power consumption of the power verification targets (31 to 35) other than the simple operation mechanisms (36, 37) from the detection value of the power meter (10) during the operation of the plurality of power verification targets (31 to 37) including the simple operation mechanisms (36, 37).

Although the present disclosure has been described in detail, the present disclosure is not limited to the embodiments described above. The embodiments described above can be modified, replaced, changed, or partially deleted in various manners without departing from the spirit of the present disclosure, as derived from the content of the claims and their equivalents. The sequence of operations and the order of processing in the above embodiments are provided as examples and are not limited to these.

For example, in the machine tool according to the present disclosure, the machine tool may be configured without a common power supply circuit, with DC conversion or other processing being executed for each power verification target. The power meter may be provided downstream of the power supply circuit. The machine tool according to the present disclosure may include any number of power verification targets. The simple operation mechanisms may be belt conveyors, air compressors, electric heaters, or other mechanisms. In the machine tool according to the present disclosure, the control device may only need to include the measurement control unit, in which the calculation control unit, the power consumption storage unit, the threshold value setting unit, and the notification unit may be optional configurations. The control device may be a computer device that controls the power verification targets via a numerical control device.

### EXPLANATION OF REFERENCE NUMERALS

1: machine tool
10: power meter
20: power supply circuit
31 to 35: servo mechanism (power verification target)
36: cooling fan (simple operation mechanism/power verification target)
37: cutting fluid pump (simple operation mechanism/power verification target)
40: control device
41: machining control unit
42: measurement control unit
43: calculation control unit
44: power consumption storage unit
45: notification unit
46: threshold value setting unit
47: life estimation unit
A: amplifier
M: motor
S: AC power source

1. A machine tool, comprising:
a plurality of power verification targets;
a power meter singly provided in an electrical pass that supplies power to all of the power verification targets; and
a control device that controls the plurality of power verification targets;
wherein the control device includes:
a measurement control unit that operates the power verification targets one at a time and measures reference power consumption of each of the power verification targets by acquiring a detection value of the power meter during an operation of the power verification targets.

2. The machine tool according to claim 1, wherein the measurement control unit operates the power verification targets at a predetermined timing.

3. The machine tool according to claim 1, wherein the control device further includes a notification unit that externally provides a notification when the reference power consumption exceeds a power threshold value set for each of the power verification targets.

4. The machine tool according to claim 3, wherein, the control device further includes a threshold value setting unit that, in a case where the power verification targets are replaced, sets the power threshold value for the replaced power verification targets, based on the reference power consumption immediately before the replacement.

5. The machine tool according to claim 1, wherein the control device further includes a power consumption storage unit that stores the reference power consumption for each of the power verification targets, and a life estimation unit that estimates life of the power verification targets, based on a plurality of values of the reference power consumption.

6. The machine tool according to claim 1, wherein the plurality of power verification targets include a servo mechanism including a motor and an amplifier.

7. The machine tool according to claim 1, wherein the plurality of power verification targets include simple operation mechanisms that are not feedback-controlled, and
the control device further includes a calculation control unit that calculates current power consumption of the simple operation mechanisms by subtracting power consumption of the power verification targets other than the simple operation mechanisms from a detection value of the power meter during an operation of the plurality of power verification targets including the simple operation mechanisms.
